(19) United States
(12) Patent Application Publication
(10) Pub. No.: US 2009/0226849 A1
(43) Pub. Date: Sep. 10, 2009

(54) EXPOSURE APPARATUS AND DEVICE MANUFACTURING METHOD

(75) Inventors: Masami Tsukamoto, Yokohama-shi (JP); Kazuhiro Takahashi, Utsunomiya-shi (JP)

Correspondence Address: CANON U.S.A. INC. INTELLECTUAL PROPERTY DIVISION, 15975 ALTON PARKWAY, IRVINE, CA, 92618-3731, US

(73) Assignee: CANON KABUSHIKI KAISHA, Tokyo (JP)

(21) Appl. No.: 12/396,282

(22) Filed: Mar. 2, 2009

(30) Foreign Application Priority Data
Mar. 4, 2008 (JP) 2008-054066

(51) Int. Cl. G03F 7/20; G03B 27/52

(52) U.S. Cl. 430/325; 355/30

(57) ABSTRACT

An exposure apparatus configured to expose a substrate using exposure light provided by a light source, comprises an optical element located in an optical path of the exposure light, a gas supply configured to supply a gas into a space including the optical path, a decomposing unit configured to process the gas supplied into the space, thereby decomposing a silicon-containing organic material in the gas, and a controller configured to control the decomposing unit to supply the gas processed by the decomposing unit to the optical element located in the space in at least an adhesion suppressed period for which adhesion of a silicon-containing organic material onto the optical element is to be suppressed, wherein the adhesion suppressed period starts when application of the exposure light onto the optical element is stopped, and ends when a predetermined time has elapsed from the start time.

### BACKGROUND OF THE INVENTION

1. Field of the Invention

The present invention relates to an exposure apparatus which projects the pattern of an original onto a substrate, thereby exposing the substrate to light, and a device manufacturing method using the exposure apparatus.

2. Description of the Related Art

In an exposure apparatus which uses ultraviolet light as the exposure light, contamination of an optical element due to small amounts of impurities contained in the atmosphere along the optical path of the exposure light poses a very serious problem because it deteriorates the optical performance of the exposure apparatus.

At present, contaminants which adhere onto an optical element in an exposure apparatus mainly include three types of materials: carboxylic acids, sulfuric materials, and silicon (Si)-containing materials (for example, organic materials containing Si0₂ or Si) . These contaminants are volatile components derived from, for example, wiring materials used in the exposure apparatus, a print circuit board (PCB), resins, grease, oils, dirt on metallic components, and the residual of a cleaner.

The silicon-containing materials of the contaminants are derived from silicon-containing organic materials generated by silicone grease or silicone resins, or those used in the process. The silicon-containing organic materials adhere onto the surface of an optical element which constitutes an optical system such as a projection optical system or illumination optical system, and turn into SiO₂ upon receiving the exposure light on that surface. Particularly when laser light is used as the exposure light, most of silicon-containing organic materials adhering on the surface of an optical element turn into SiO₂ and are deposited on that surface in layers. The deposition of SiO₂ on the surface of the optical element largely changes the characteristics of the transmittance of an antireflection coating and the reflectance of a reflection coating even if the amount of deposition is small. This results in a decrease and nonuniformity in the illuminance of the exposure light. Still worse, it is difficult to remove the SiO₂ deposited on the surface of the optical element, so the optical element must often inevitably be replaced. For these reasons, the silicon-containing materials are thought to be most problematic of the contaminants.

Silicon-containing organic materials contained in the gas in an exposure apparatus can be detected by, for example, the gas chromatograph mass spectrometer (GC-MS) . In general, because the density of silicon-containing organic materials is very low, a gas is introduced into a so-called adsorbent tube, which is filled with an adsorbent, over a predetermined period of time to make the adsorbent adsorb the silicon-containing organic materials. After that, the silicon-containing organic materials are desorbed and analyzed by, for example, the GC-MS. Trimethylsilanol (TMS), tetramethyldisiloxane (M2), three-membered cyclic siloxane (D3) to six-membered cyclic siloxane (D6), more-membered cyclic siloxanes, and the like can be detected as the silicon-containing organic materials. Silicon-containing materials other than those mentioned above can be detected when they are employed in the members used or the process.

In the resist process, tetramethyldisilazane (HMDS) is often used and detected as TMS and M2 by the GC-MS. The tendency of adhesion onto an optical element slightly differs between these materials, but their difference falls within about several times. Hence, the total density of these materials obtained by evaluating their qualities and determining their quantities can be interpreted as representing the degree that a gas containing these materials is expected to make silicon-containing materials adhere onto an optical element.

In an exposure apparatus which uses an ArF laser, most of silicon-containing materials are deposited on the surface of an optical element as SiO₂. The rate of deposition depends on the use conditions of the optical element, such as the flow rate of the gas and the illuminance of the exposure light. For example, according to an experimental result, when an optical element facing the upper surface of an original (reticle) is used for about a month at a silicon-containing organic material density of 1.5 μg/m³, SiO₂ having a thickness of 4 nm is deposited on the optical element, and the transmittance of the deposition portion decreases by about 1.2%. The optical element in this case must be replaced in about, for example, three months.

To combat the problematic contamination of an optical element as mentioned above, there is a method of dividing the optical path into individually partitioned spaces, and purging the spaces by an inert gas such as clean air or nitrogen gas, thereby decreasing the density of contaminants in the spaces. There is also a method of removing the contaminants by, for example, a filter. These methods are effective in portions, where the interiors of the individually partitioned spaces are easily maintained clean, such as an illumination optical system and projection optical system. However, it is difficult to isolate optical elements located near stages such as an original stage and substrate stage because of the movement of the stages. Furthermore, in the peripheries of the stages, there is a large number of components, which contain outgassing members, such as movable components and control components, so the effect of, for example, a filter is hard to obtain. Therefore, contamination readily occurs in optical elements positioned in the boundaries between the partitioned spaces and a non-partitioned space, particularly, the final optical element of the illumination optical system facing the upper surface of the original, the first optical element of the projection optical system facing the lower surface of the original, and the final optical element of the projection optical system facing the substrate surface. Periodical replacement of these optical elements is inevitable.

Japanese Patent Laid-Open No. 2006-32991 proposes a method of supplying an inert gas containing a small amount of oxygen into a space including an optical element to generate ozone from the oxygen by irradiating it with exposure light, thereby cleaning the lens. This method is effective in removing hydrocarbon-based materials which have already been deposited on the lens, but it cannot remove SiO₂ deposited on the lens. This method is therefore ineffective in contamination due to silicon-containing organic materials.

Japanese Patent Laid-Open No. 2005-236079 discloses a technique of generating ozone by an ozone generator, and diluting the generated ozone, thereby generating a high-transmittance purge gas containing an adjusted amount of ozone, simultaneously with exposure of a semiconductor substrate. However, Japanese Patent Laid-Open No. 2005-236079 does not take account of adhesion of silicon-containing organic materials onto an optical element after the end of the application of the exposure light to the substrate, and contamination of the optical element due to the adhesion.

Japanese Patent Laid-Open No. 2006-120825 discloses a method of precipitating impurities in advance by applying ultraviolet rays to an optical element in order to remove the impurities.

### SUMMARY OF THE INVENTION

The present invention has been made in consideration of the above-described situation, and has as its object to effectively suppress the deposition of, for example, SiO₂ on an optical element inserted in the optical path of exposure light.

According to the first aspect of the present invention, there is provided an exposure apparatus which projects a pattern of an original onto a substrate using exposure light provided by a light source, thereby exposing the substrate to light, the apparatus comprising an optical element located in an optical path of the exposure light, a gas supply configured to supply a gas into a space including the optical path, a decomposing unit configured to process the gas supplied into the space by the gas supply, thereby decomposing a silicon-containing organic material in the gas, and a controller configured to control the decomposing unit, wherein the controller is configured to control the decomposing unit to supply the gas processed by the decomposing unit to the optical element located in the space in at least an adhesion suppressed period for which adhesion of a silicon-containing organic material onto the optical element is to be suppressed, and the adhesion suppressed period starts when application of the exposure light onto the optical element is stopped, and ends when a predetermined time has elapsed from the start time.

According to the second aspect of the present invention, there is provided a device manufacturing method comprising the steps of exposing a substrate coated with a photosensitive agent to light using an exposure apparatus, and developing the photosensitive agent, wherein the exposure apparatus is configured to project a pattern of an original onto the substrate using exposure light provided by a light source, thereby exposing the substrate to light, and comprises an optical element located in an optical path of the exposure light, a gas supply configured to supply a gas into a space including the optical path, a decomposing unit configured to process the gas supplied into the space by the gas supply, thereby decomposing a silicon-containing organic material in the gas, and a controller configured to control the decomposing unit, wherein the controller is configured to control the decomposing unit to supply the gas processed by the decomposing unit to the optical element located in the space in at least an adhesion suppressed period for which adhesion of a silicon-containing organic material onto the optical element is to be suppressed, and the adhesion suppressed period starts when application of the exposure light onto the optical element is stopped, and ends when a predetermined time has elapsed from the start time.

Further features of the present invention will become apparent from the following description of exemplary embodiments with reference to the attached drawings.

### BRIEF DESCRIPTION OF THE DRAWINGS

FIG. 1 is a view showing the schematic arrangement of an exposure apparatus according to the first embodiment of the present invention;

FIG. 2 is a view showing an example of the arrangement of an ozone generator in the first embodiment of the present invention;

FIG. 3 is a view showing the schematic arrangement of an exposure apparatus according to the second embodiment of the present invention;

FIG. 4 is a view showing an example of the arrangement of an ozone generator in the second embodiment of the present invention;

FIG. 5 is a view showing the schematic arrangement of an exposure apparatus according to the third embodiment of the present invention;

FIG. 6 is a view showing the schematic arrangement of an exposure apparatus according to the fourth embodiment of the present invention;

FIG. 7 is a view showing the schematic arrangement of an exposure apparatus according to the fifth embodiment of the present invention;

FIG. 8 is a view showing the schematic arrangement of an exposure apparatus according to the seventh embodiment of the present invention;

FIG. 9 is a view showing the schematic arrangement of an exposure apparatus according to the eighth embodiment of the present invention; and

FIG. 10 is a view showing the schematic arrangement of an exposure apparatus according to the ninth embodiment of the present invention.

### DESCRIPTION OF THE EMBODIMENTS

Preferred embodiments of the present invention will be described below with reference to the accompanying drawings.

An exposure apparatus projects the pattern of an original (reticle) onto a substrate (wafer) using exposure light provided by a light source, thereby exposing the substrate to light. The exposure apparatus includes, in the optical path of the exposure light as optical systems, an illumination optical system which illuminates the original, and a projection optical system which projects the pattern of the original onto the substrate. Each of the illumination optical system and the projection optical system includes a plurality of optical elements, which are located in the optical path of the exposure light as well. The entire exposure apparatus is accommodated in a temperature-regulated chamber. The chamber has a plurality of partitioned spaces which are further isolated from the internal atmosphere of the chamber. The plurality of partitioned spaces is controlled so as to minimize the generation of contaminants by being purged by a clean atmosphere. The plurality of optical elements is separately accommodated in the plurality of internal spaces in order to prevent their contamination. However, the side surfaces of optical elements, which are located at the ends of the partitioned spaces, of the plurality of optical elements are exposed to a non-partitioned space which is not isolated from the internal atmosphere of the chamber. Because it is more difficult to control the atmosphere to which the optical elements exposed to the non-partitioned space are subjected than in the partitioned spaces, these optical elements are a typical example of an optical element having a surface on which silicon-containing materials are readily deposited. For example, the vicinity of the original or substrate is often the non-partitioned space because an original stage which holds and moves the original or a substrate stage which holds and moves the substrate are located. In this case, the side surface of an optical element facing the original or substrate is exposed to the non-partitioned space in the chamber.

On an optical element located in a space including the optical path of the exposure light, SiO₂ derived from silicon-containing organic materials contained in a gas which composes the atmosphere in the space is deposited. The inventor of the present invention analyzed the deposition mechanism as follows. While light is not applied to an optical element, silicon-containing organic materials are adsorbed onto the surface of the optical element. After that, when light is applied to the optical element, the silicon-containing organic materials turn into SiO₂ by a chemical reaction. Particularly in an exposure apparatus which uses laser light as the exposure light, when a laser light pulse is applied to an optical element, most of organic materials other than silicon-containing organic materials adsorbed on the surface of the optical element desorb from the surface, which is cleaned up accordingly. The silicon-containing organic materials are decomposed, so their hydrocarbon components are removed from the surface of the optical element, but the silicon atoms are oxidized and stay behind on the surface of the optical element as SiO₂. During the time from when the application of a laser light pulse to the optical element stops until the next pulse is applied to it, the organic materials in the atmosphere are adsorbed onto the surface of the optical element again. Upon repetition of the adsorption and the reaction by laser light irradiation, SiO₂ is deposited on the surface of the optical element. Note that immediately after laser light irradiation, adsorption rapidly occurs because the surface of the optical element is clean. Then, the amount of adsorption increases gradually, but the rate of adsorption slows down as compared with the initial rate of adsorption.

To suppress the deposition of SiO₂, it is important to decrease the amount of silicon-containing organic materials adsorbed onto the surface of an optical element while light is not applied to the optical element, in other words, the time between successive pulses and before and after a group of laser light pulses is applied to the optical element.

An exposure apparatus according to a preferred embodiment of the present invention includes a gas supply which supplies a gas into a space including the optical path of exposure light, a decomposing unit which processes the gas supplied into the space by the gas supply, thereby decomposing silicon-containing organic materials in the gas, and a controller which controls the decomposing unit. The controller controls the decomposing unit to supply the gas processed by the decomposing unit to an optical element located in the space, in at least an adhesion suppressed period for which adhesion of silicon-containing organic materials onto the optical element is to be suppressed. The adhesion suppressed period starts when application of the exposure light to the optical element is stopped, and ends when a predetermined time has elapsed from the start time.

A pulse oscillated laser can typically be used as the light source. In this case, laser light serving as the exposure light is not applied to the optical element in the period between successive pulses of the laser light. In this period, the density of silicon-containing organic materials needs to be decreased satisfactorily. Typically, the period between successive pulses during exposure in individual shot regions is sufficiently shorter than the adhesion suppressed period, so the controller can control the decomposing unit to continuously operate during exposure in individual shot regions. If the period between successive exposure operations in shot regions falls within the adhesion suppressed period, the controller can control the decomposing unit to continuously operate. If the period between successive exposure operations in shot regions falls outside the adhesion suppressed period, a gas which is not processed by the decomposing unit may be supplied into the space after the lapse of the adhesion suppressed period.

The controller operation to control the gas supply is typically interlocked with control of a substrate exposure operation which accompanies application of the exposure light onto the optical element. This interlocked operation can be implemented by the issuance of an exposure operation control signal or instruction, or starting time measurement upon execution of program steps and instructing the gas supply to stop its operation upon reaching the end of time measurement which determines the end time of the adhesion suppressed period.

The controller typically operates the decomposing unit prior to the exposure operation to supply the gas processed by the decomposing unit into the space before the exposure operation starts.

Immediately after the end of the substrate exposure which accompanies application of the exposure light to the optical element, the surface of the optical element is clean and therefore is in an active state in which molecules are more likely to adhere onto the surface. As molecules adhere onto the surface and the surface is covered with the molecules, the surface changes into an inactive state in which molecules are less likely to adhere onto the surface. The adhesion suppressed period is the period in which the surface in an active state becomes inactive, and a precise time length can be determined by, for example, an experiment. Note that leaving the decomposing unit to operate even after the adhesion suppressed period may lead to, for example, deterioration in a member which comes into contact with the gas through the decomposing unit, and deterioration in the decomposing unit itself.

The adhesion suppressed period can be determined in accordance with, for example, the flow rate of the gas, the density of silicon-containing organic materials, and the illuminance of the exposure light. When, for example, the flow rate is 0.3 m/sec, the density of siloxanes serving as the silicon-containing organic materials is 0.4 μg/m³, and the illuminance of the exposure light is 0.1 mJ/(cm²-pulse), the rate of adhesion of the siloxanes onto the optical element reaches a nearly saturation level in about several milliseconds. Even when the fact that the illuminance, density, and flow rate increase from these conditions is taken into consideration, the surface of the optical element becomes almost inactive if the adhesion suppressed period is set to about 0.1 seconds or about 1 second at a maximum. This makes it possible to suppress further adhesion of molecules.

A preferable example of the decomposing unit which decomposes silicon-containing organic materials is an ozone generator which adds ozone to a gas supplied into a space including the optical path of the exposure light by the gas supply. The addition of ozone makes it possible to decrease the density of silicon-containing organic materials on the surface of the optical element located in the space, thus suppressing adhesion of SiO₂ onto the surface of the optical element. Note that if the atmosphere in the space including the optical path of the exposure light contains oxygen, ozone is generated upon irradiating the oxygen with the exposure light but it cannot suppress adhesion of SiO₂ onto the optical element.

The density of silicon-containing organic materials which stay behind in an exposure apparatus including a filter is normally about several μg/m³. The efficiency of decomposition of the silicon-containing organic materials by ozone changes depending on the density of silicon-containing organic materials and other environmental conditions. In one example, when ozone at a density of about 0.3 ppm is added to an atmosphere containing silicon-containing organic materials at a density of about several μg/m³, it is possible to decompose about 70 to 80% of the silicon-containing organic materials. The decomposition efficiency slightly improves upon increasing the ozone density, but it reaches a nearly saturation level of about 90% at an ozone density of 0.5 ppm or more.

Ozone oxidizes and deteriorates metals, resins, and the like, so continuously feeding ozone with a high density into the exposure apparatus deteriorates constituent components of the exposure apparatus, which come into contact with the ozone. To avoid this situation, Japanese Patent Laid-Open No. 2006-32991 sets a cleaning mode separately from an exposure mode, and cleans the optical elements in the cleaning mode. Japanese Patent Laid-Open No. 2005-236079 continuously feeds ozone with a high density as well, so the exhaust and intake units have a large, complicated structure including an exhaust pump and a mass flow controller. However, an ozone density of 0.5 ppm or less has little influence on constituent components of the exposure apparatus, and can be continuously fed over a long period of time without any problem. Also, an ozone density of 0.5 ppm or less is nearly equal to the density of ozone generated upon exposure in the exposure apparatus, and has little influence on the process as well. An ozone density of 0.5 ppm or less has little influence on the refractive index of the atmosphere in the optical path and makes it hard for ozone to absorb the exposure light. This obviates the need for a special supply/exhaust structure and other large-scale measurement and control systems, thus making it possible to provide a desired performance by a simple system. Hence, the ozone density is preferably 0.5 ppm or less.

While the ozone generator needs to be located upstream of the optical path into which a gas is supplied by the gas supply, a source of silicon-containing organic materials need not always be located upstream of that optical path because the lifetime of ozone is long.

If the exposure light is absorbed by ozone or a component having a low resistance to ozone lies around the optical path, the ozone sometimes adversely affects the exposure process. In this case, it is desirable to remove the silicon-containing impurity materials by temporarily adding ozone to the channel through which the gas flows by the ozone generator, and immediately remove the ozone by an ozone removing unit thereafter. For example, if the atmosphere circulates through the exposure apparatus, adding ozone to the gas in a part of the circulation system makes it possible to decrease the silicon-containing organic materials generated in the exposure apparatus, and return the ozone into the optical path by removing the ozone from the gas thereafter. Note that it is more effective to mix ozone into the gas at positions close to optical elements because there is normally a plurality of sources of silicon-containing organic materials in the exposure apparatus. Also, a space which is conventionally set as the non-partitioned space may be set as the partitioned space because an optical element exposed to the non-partitioned space is readily contaminated, as mentioned above. Supplying the gas processed by the decomposing unit into the partitioned space makes it possible to prevent contamination of all optical elements. It is especially desirable to supply the gas processed by the decomposing unit into a partitioned space including the gap between the original or substrate and an optical element facing it. Because contaminants are often generated by a component (for example, a PC board or a cable) for driving the original stage or substrate stage, isolating the component makes it possible to prevent the original or substrate and the optical element facing it from being contaminated by the contaminants generated by the component. Moreover, since the decomposing unit can decompose even the contaminants remaining in the gap between the original or substrate and the optical element facing it, it is possible to effectively suppress contamination of the optical element. The use of an ozone generator as the decomposing unit has another merit of suppressing the adverse influence of ozone from reaching other components (for example, components for driving the stages) which constitute the exposure apparatus.

An ultraviolet lamp for generating ozone (ozone lamp), for example, is preferable as the ozone generator. A relatively compact ozone lamp can be used in generating ozone at a density as low as, for example, 0.5 ppm or less. Ultraviolet rays generated by the ozone lamp influence the resist, so the ozone generator may be arranged outside the exposure area, a gas containing ozone at a density higher than a target density may be generated, and it may be mixed into the atmosphere in the exposure apparatus. Even when the atmosphere in the exposure apparatus is nitrogen or the like, a separate atmosphere may be ozonized and mixed in the same way.

The ozone density can be adjusted by adjusting the output from the ultraviolet lamp of the ozone generator or the area of irradiation of a gas containing oxygen with ultraviolet rays by taking account of, for example, the flow rate. An ozone densitometer may be provided to adjust the amount of ozone generation of the ozone generator in accordance with the measurement value obtained by it.

It is desirable to ensure a sufficient ozone density at the start of exposure. It is therefore effective to start exposure by providing an ozone densitometer at a predetermined position, activating the decomposing device in advance before the start of exposure, and confirming that the ozone density has reached a predetermined density, or to activate the decomposing device prior to exposure by the time taken for the ozone density to reach a predetermined density. In addition, to prevent ozone generation more than necessary, it is desirable to be able to turn on/off ozone generation. To attain this operation, activation of the decomposing device is interlocked with the exposure timing of an exposure system. This makes it possible to effectively suppress lens contamination while preventing the adverse influence of ozone on the exposure operation.

Other methods can be used to decompose the silicon-containing organic materials. For example, the silicon-containing organic materials can be decomposed by plasma generated by a plasma generator. Alternatively, the silicon-containing organic materials can be decomposed by a photocatalyst. The plasma generator or photocatalyst can be located on a route of gas supply into a space including the optical path of the exposure light.

As for the plasma decomposition, a plasma including radicals is generated by corona discharge in a plasma generation unit including a discharge electrode and counter electrode, and the silicon-containing organic materials in the atmosphere are decomposed by the radicals. Ozone is generated together with the radicals, and contributes to decomposing the silicon-containing organic materials as well. The photocatalyst is, for example, TiO₂ and is activated upon being irradiated with ultraviolet rays to decompose the silicon-containing organic materials. Since both the methods decompose the silicon-containing organic materials, they can suppress the deposition of SiO₂ on the optical element.

In these methods including that which uses ozone, a high humidity of the atmosphere in the space including the optical path can accelerate the decomposition of the silicon-containing organic materials. It is therefore preferable to humidify a gas supplied into the space as long as the humidification has no influence on the exposure. If a dry atmosphere is required for exposure, a regulator for controlling the atmospheric humidity may be provided in the exposure apparatus to humidify a region where the decomposing unit decomposes the silicon-containing organic materials.

More detailed embodiments of the present invention will be described below.

### FIRST EMBODIMENT

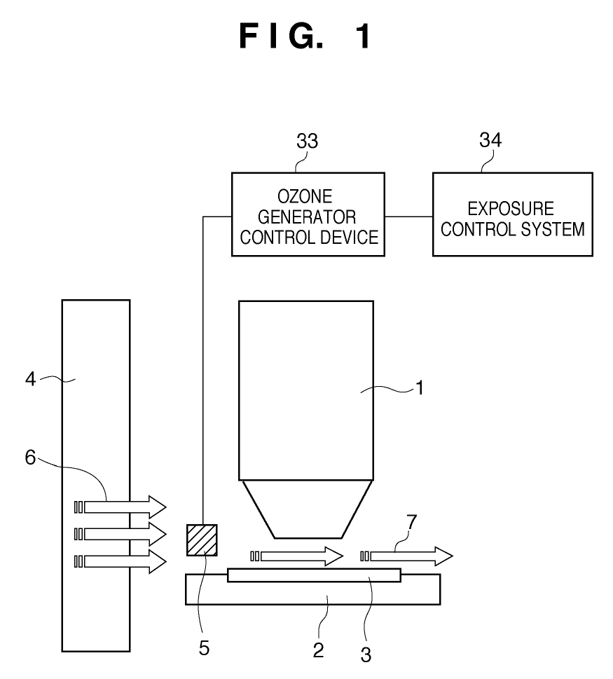

FIG. 1 is a view showing the schematic arrangement of an exposure apparatus according to the first embodiment of the present invention. The exposure apparatus shown in FIG. 1 projects the pattern of an original (a reticle; not shown) onto a substrate (wafer) 3 by a projection optical system 1 using exposure light provided by a light source (not shown), thereby exposing the substrate to light. The original is illuminated by an illumination optical system (not shown) in an exposure operation on the substrate 3. The illumination optical system and projection optical system 1 are accommodated in a temperature-regulated chamber having undergone foreign substance and chemical cleaning measures. The projection optical system 1 and a substrate stage (wafer stage) 2 are supplied with temperature-regulated air (gas) from a temperature regulating unit (gas supply) 4, thereby being maintained at a predetermined temperature. The temperature regulating unit 4 mounts a chemical filter to remove impurities contained in the air.

The atmosphere around the projection optical system 1 can contain volatile components of silicon-containing organic materials from silicone grease used in a driving system of the substrate stage 2, a silicone potting agent used in the peripheral control board, and cables. The final optical element of the projection optical system 1 is exposed to these volatile components. Therefore, in the conventional arrangement, SiO₂ is gradually deposited on the final optical element upon long-term use and its property may change.

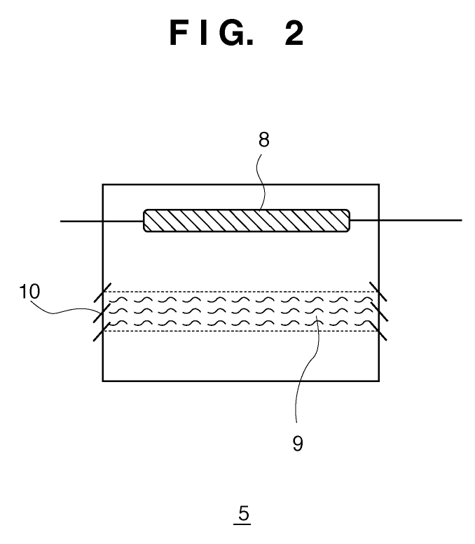

In the exposure apparatus according to this embodiment, an ozone generator 5 serving as a decomposing unit which decomposes silicon-containing organic materials is located near the gas outlet of the temperature regulating unit 4 sideways on the lower side of the projection optical system 1. The ozone generator 5 includes, for example, an ultraviolet lamp 8 for generating ozone, as illustrated in FIG. 2. As light leaks from the ultraviolet lamp 8, it may expose the resist applied on the substrate 3 to light. To avoid this situation, the ultraviolet lamp 8 is placed in a light-shielded box so that air to be supplied into the optical path flows through an air channel 9 in the box. A light-shielding member 10 can be attached to the outlet/inlet of the air channel 9 so as to prevent the generation of leaked light. The ultraviolet lamp 8 is configured to be able to be ON/OFF-controlled by a control device (controller) 33. As the ultraviolet lamp 8 is turned on, ozone is generated in the air. A slit member is inserted between the ultraviolet lamp 8 and the air channel 9. The ozone density in the optical path can be adjusted to about, for example, 0.2 ppm by controlling the opening ratio of the slit of the slit member. The control device 33 is interlocked with an exposure control system 34 to operate the ozone generator 5 ten seconds before the start of measurement for exposure preparation, and stops it five seconds after the end of exposure.

In this exposure apparatus, according to the analysis of the air near the lower portion of the projection optical system 1 when the ozone generator 5 was OFF, the density of silicon-containing organic materials (the total density of TMS, M2, and D3 and more-membered cyclic siloxanes) was 4.5 μg/m³. A decrease in the transmittance of the projection optical system 1 was 0.16%/BP (10⁹ pulses).

When continuous exposure was performed in a stable state by operating the ozone generator 5, the density of silicon-containing organic materials decreased to 1.7 μg/m³ from that in the above case. When exposure was performed under this condition, a decrease in the transmittance of the projection optical system 1 dropped to 0.06%/BP from that in the above case.

### SECOND EMBODIMENT

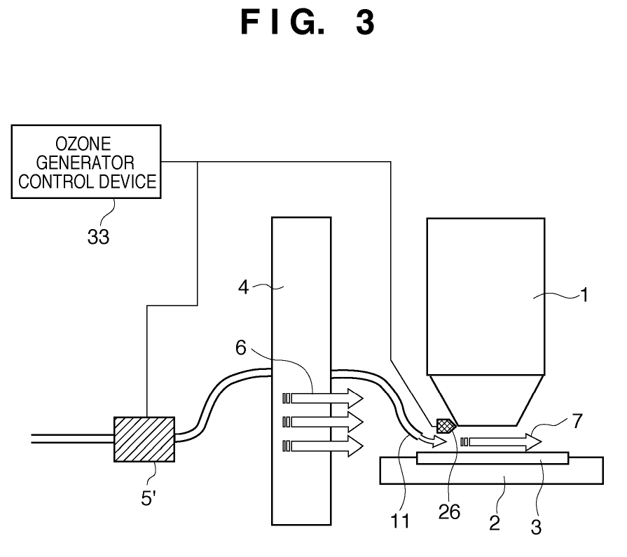

FIG. 3 is a view showing the schematic arrangement of an exposure apparatus according to the second embodiment of the present invention. The second embodiment is different from the first embodiment in that an ozone generator 5′ is located outside a chamber of the exposure apparatus.

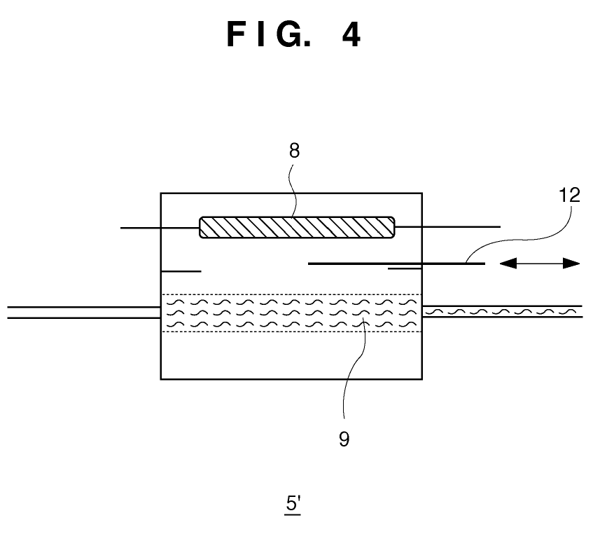

FIG. 4 is a view showing an example of the arrangement of the ozone generator. An ultraviolet lamp 8 for generating ozone is located on one side of a channel 9 including a quartz pipe for supplying clean air. In the ozone generator 5′, when air supplied from a utility pipe flows through the air channel 9 which transmits ultraviolet rays, it generates ozone upon receiving ultraviolet rays from the ultraviolet lamp 8. The air containing the ozone is supplied into the chamber of the exposure apparatus through piping. An ozone densitometer 26 is located upstream of the optical path near the exposure area to monitor the ozone density, and the ozone density is controlled by a control device 33. The ozone density is controlled by changing the irradiation region of the clean air by opening/closing a light-shielding plate 12 which is inserted between the ultraviolet lamp 8 and the air channel 9 including a quartz pipe and controls the irradiation region.

The control device 33 is interlocked with an exposure control system (not shown), so that it turns off the ultraviolet lamp 8 at a timing, which allows ensuring the above-mentioned adhesion suppressed period, when the exposure operation is kept OFF in excess of the above-mentioned adhesion suppressed period, for example, during maintenance and exposure apparatus mask replacement. This reduces the adverse influence of ozone on the peripheral components in the optical path. Also, the control device 33 operates the ozone generator 5 prior to the start of the exposure operation so as to start the exposure operation after the ozone density has reached a predetermined density.

Ozone is supplied to the vicinity of a projection optical system 1 by blowing out air containing the ozone from an ozone supply port 11. A predetermined amount of clean air is supplied to the ozone generator 5′ outside the chamber of the exposure apparatus to generate ozone in the air, and the air containing the ozone is supplied to the ozone supply port 11. When air-containing ozone at a density of 2 ppm was supplied from the ozone supply port 11 at a flow rate of 3 l/min, the average ozone density on the downstream side near the lower end of the projection optical system 1 was 0.3 ppm.

In this case, the density of silicon-containing organic materials (the total density of TMS, M2, and D3 and more-membered cyclic siloxanes) decreased to 1.4 μg/m³, and a decrease in the transmittance of the projection optical system 1 dropped to 0.05%/BP.

The ozone supply port 11 may have, for example, a nozzle structure in order to more efficiently supply an ozone-containing gas to a targeted optical element.

### THIRD EMBODIMENT

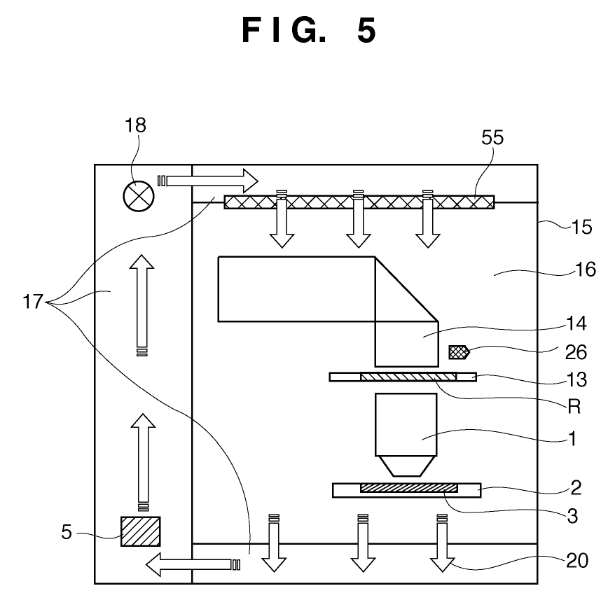

FIG. 5 is a view showing the schematic arrangement of an exposure apparatus according to the third embodiment of the present invention. The entire exposure apparatus is accommodated in a chamber 15 for controlling the temperature and cleanliness. Laser light guided into the chamber 15 by a light extension optical system from a laser light source (not shown) located outside the chamber 15 is shaped by an illumination optical system 14, and illuminates an original (reticle) R on an original stage (reticle stage) 13. With this operation, the pattern of the original R is projected onto a substrate 3 on a substrate stage 2 by a projection optical system 1.

The chamber 15 accommodates an exposure apparatus portion 16 and circulation unit (gas supply) 17. The chamber 15 has a circulation structure formed, which returns the atmosphere (gas) in the exposure apparatus portion 16 to the exposure apparatus portion 16 by a fan 18 inserted in the circulation unit 17. In the exposure apparatus portion 16, air is blown out from the ceiling of the chamber 15, the air is recovered by the floor of the chamber 15, its temperature and cleanliness are regulated through a temperature regulating system (not shown) in the circulation unit 17 and a filter 19, and the air is supplied from the ceiling to the exposure apparatus portion 16 again.

An ozone generator 5 is provided in the circulation unit 17, and adds ozone to the atmosphere (gas) in the circulation unit 17. The ozone generator 5 includes an ultraviolet lamp for generating ozone, and adjusts the ozone density by changing the irradiation region of the atmosphere. An ozone densitometer 26 located upstream of the original stage 13 near the original stage 13 (upstream of the optical path) measures the ozone density, and an ozone generator control device controls the ozone generator 5 based on the measurement result so that the ozone density stays at a target density. The ozone generator control device to control the ozone generator 5 is interlocked with an exposure control system. During, for example, a process which comes under a large influence of ozone, the ozone generator control device can control the ozone generator 5 to decrease the ozone density or stop ozone generation. Also, during, for example, maintenance, the ozone generator control device can control the ozone generator 5 to stop ozone generation. When the ozone generator 5 shifts from an OFF state to the exposure operation, it is activated in advance and starts exposure operation after the ozone density has reached a predetermined density.

The density of silicon-containing organic materials measured in front of the ozone generator 5 in the circulation unit 17 was 4.3 μg/m³. When ozone at a density of about 0.25 ppm was added to a circulating gas by the ozone generator 5, the density of silicon-containing organic materials on the outlet side of an ozone decomposing device located downstream of the ozone generator 5 on the ceiling of the circulation unit 17 changed to 1.1 μg/m³. The rate of decrease in the illuminance on the image plane of the exposure apparatus was 3.1%/BP when the ozone generator 5 was not used, but it changed to 0.9%/BP after the ozone generator 5 was used. The filter was replaced when the illuminance decreased by about 5%. Filter replacement was necessary in little less than 1.6 months when the ozone generator 5 was not used, but the use of the ozone generator 5 prolonged the lifetime of the filter to 5.5 months.

### FOURTH EMBODIMENT

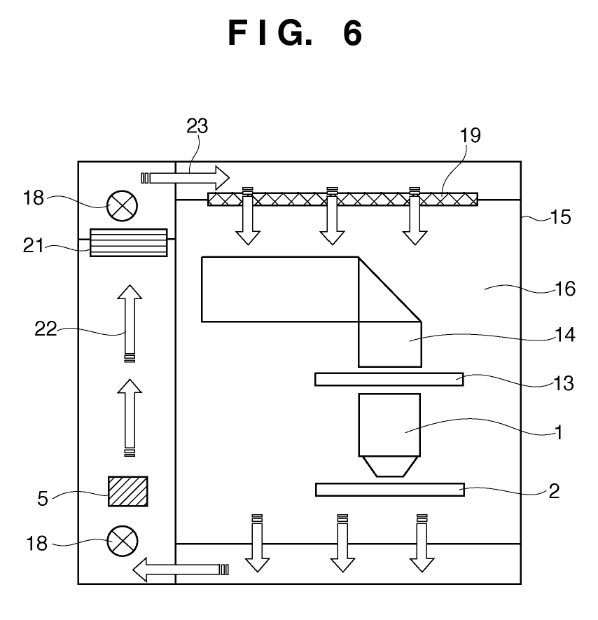

In an exposure apparatus similar to that in the third embodiment, providing an ozone killer 21 in a circulation unit 17, as illustrated in FIG. 6, makes it possible to reduce the adverse influence of ozone on components in an exposure apparatus portion 16. Ozone is added by an ozone generator 5 to the atmosphere (gas) recovered from the floor of the exposure apparatus portion 16 into the circulation unit 17, is decomposed by an ozone decomposing device located on the ceiling of the circulation unit 17, and is returned into the exposure apparatus portion 16 through a filter 19. The ozone decomposition can use a material formed by supporting an ozone decomposition catalyst on a ceramic base material. This makes it possible to suppress the ozone density at 0.02 ppm or less, thus reducing, for example, the adverse influence of ozone on the resist process and deterioration in components having no resistance to ozone.

### FIFTH EMBODIMENT

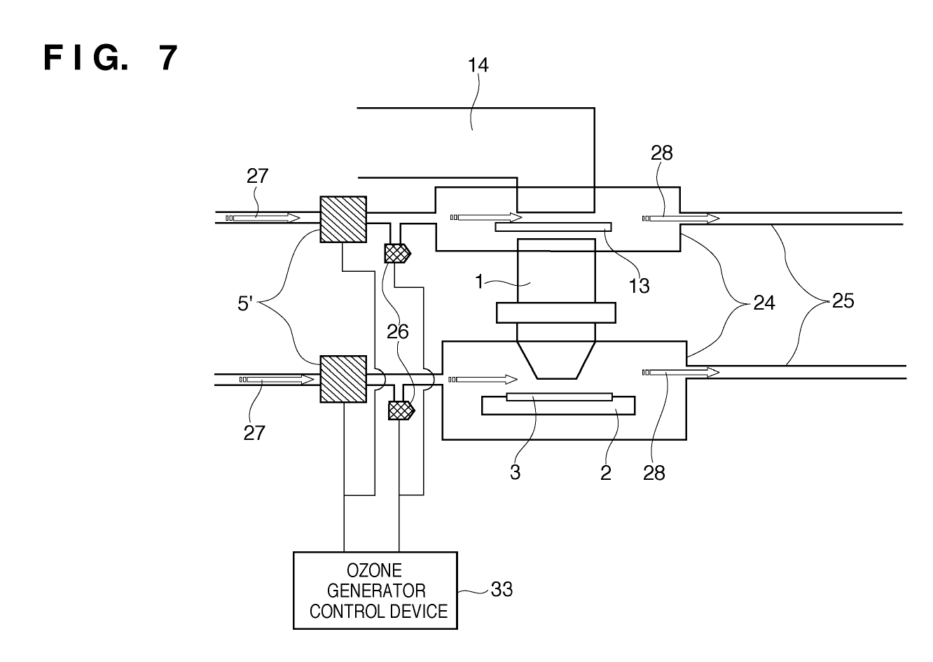

FIG. 7 is a view showing the schematic arrangement of an exposure apparatus according to the fifth embodiment of the present invention. In this embodiment, in a chamber which accommodates the entire exposure apparatus, the peripheries of an original stage 13 and substrate stage 2 are partitioned, and the partitioned spaces are individually purged, as illustrated in FIG. 7. Contaminant density control is facilitated by limiting the environment control regions of the exposure apparatus and individually controlling them. By locating components that become contamination sources outside the partitions as much as possible, the contaminant density inside the partitions can be suppressed lower than that outside the partitions (chamber space) . Ozone generators 5′ are located on the inlet sides of regions 24 which are purged individually, and ozone densitometers 26 are inserted between the ozone generators 5′ in the purge channel and the optical path, thereby monitoring the ozone density. The ozone density can be adjusted by opening/closing a light-shielding plate of an ultraviolet lamp, as mentioned above. The ultraviolet lamp is turned on in advance at the start of exposure, and exposure is started after the ozone density has reached a predetermined density. After the end of exposure, the ozone density is maintained at the predetermined density for a predetermined time, and the ultraviolet lamp is then turned off.

When ozone at a density of 0.3 ppm was added to purge air by the ozone generator 5′, the density of silicon-containing organic materials, which was 3.7 μg/m³ at the purge outlet before their mixture, changed to 0.7 μg/m³. This decreased the rate of adhesion of these materials onto the optical element to about ⅕ that before the addition. The use of a system which individually purges only necessary regions allows reduction in deterioration in peripheral components due to the presence of ozone.

### SIXTH EMBODIMENT

A case in which an ozone densitometer 26 is not used in an exposure apparatus similar to that in the fifth embodiment will be exemplified. The time from when an ultraviolet lamp of an ozone generator 5′ is turned on until the ozone density reaches a predetermined density, and that from when the ultraviolet lamp is turned off until the ozone density starts to decrease are measured. At the start of exposure, the ultraviolet lamp is turned on prior to the former time. At the end of exposure, the ultraviolet lamp is turned off after the lapse of a time obtained by subtracting the time until the ozone density starts to decrease from the time for which the ozone density is desirably maintained at the predetermined density. The ultraviolet lamp is turned on 2 minutes before the start of exposure, and it is turned off 20 seconds after the end of exposure, thereby obtaining the same effect as in the fifth embodiment.

### SEVENTH EMBODIMENT

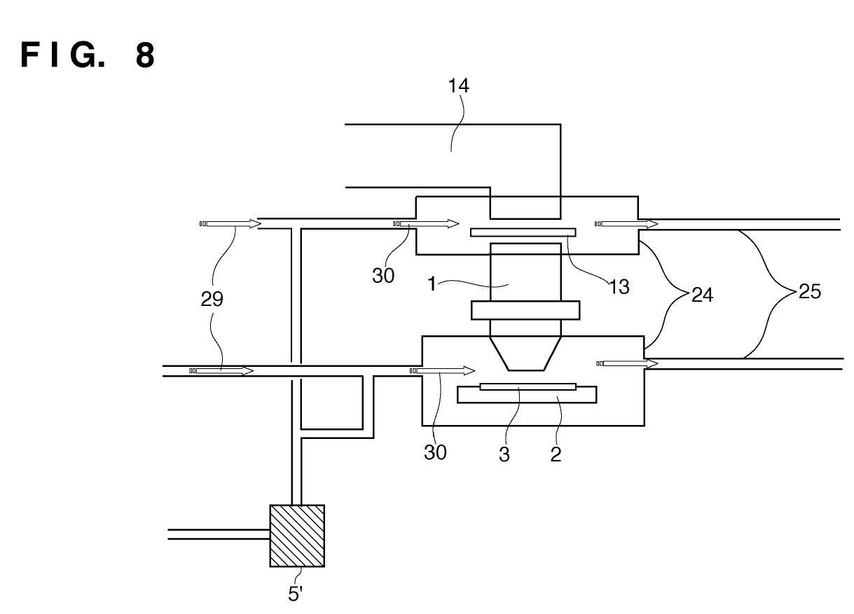

FIG. 8 is a view showing the schematic arrangement of an exposure apparatus according to the seventh embodiment of the present invention. A purge is performed using a purge gas, which does not contain oxygen, such as nitrogen gas in the exposure apparatus in which the peripheries of an original stage and substrate stage are purged individually, as in the fifth embodiment. In this case, no ozone is generated even by applying ultraviolet rays to the purge gas by an ultraviolet lamp for generating ozone. To cope with this situation, a separate line of air is provided to generate ozone in the air by the line, the ozone density and the air flow rate are adjusted so that the ozone density reaches a desired density, and the air is added to the atmospheric gas.

To purge the individual purge spaces, nitrogen is supplied into them at a flow rate of 10 l/min. When air-containing ozone at a density of 50 ppm is added to the atmospheric gas, the nitrogen in the purge area of an optical element contains ozone at a density of 0.25 ppm. With this operation, silicon-containing organic materials are decomposed in the periphery of the optical element, and therefore the density decreases, thus suppressing the deposition of SiO₂. The density of silicon-containing organic materials, which was 4.7 μg/m³ at the purge outlet before the addition, changed to 1.3 μg/m³. This decreases the rate of adhesion of the silicon-containing organic materials onto the optical element to about ¼ that before the addition.

### EIGHTH EMBODIMENT

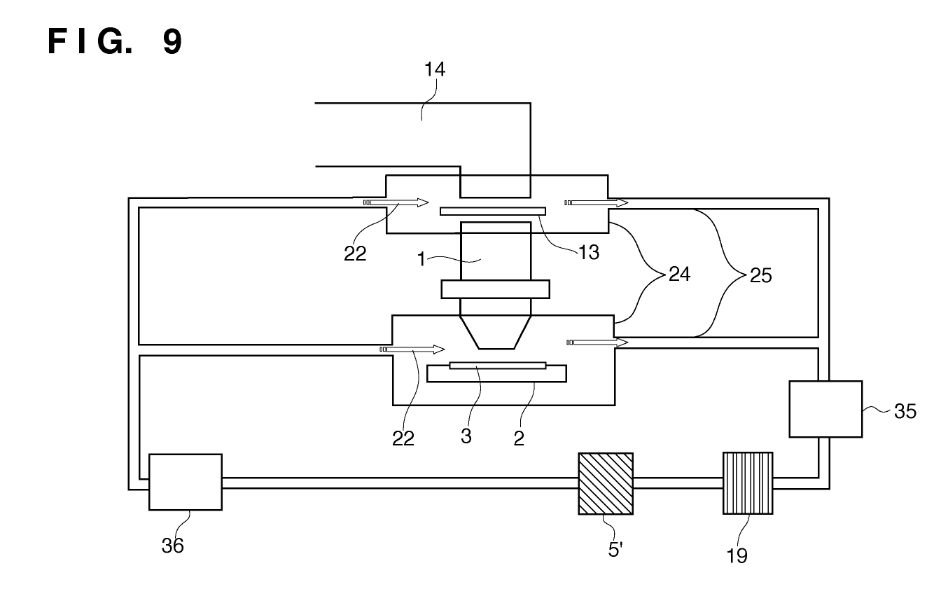

FIG. 9 is a view showing the schematic arrangement of an exposure apparatus according to the eighth embodiment of the present invention. A purge is performed using dry air in the exposure apparatus in which the peripheries of an original stage and substrate stage are purged individually, as in the fifth embodiment. After purging the vicinity of the optical path, the air undergoes impurity removal in the channel, is returned into the optical path again, and is circulated through the channel. In the circulation channel, the air is humidified to have a humidity of 5% or more by a humidifier 35, is added with ozone by an ozone generator 5′ so that impurities contained in it are decomposed, is dehumidified to have a humidity less than 5% by a dehumidifier 36, and is returned into the optical path. When ozone at a density of 0.25 ppm was mixed into the purge air by the ozone generator 5′, the density of silicon-containing organic materials, which was 5.8 μg/m³ at the purge outlet when the ozone generator 5′ was OFF, changed to 0.8 μg/m³ upon the humidification. The density of silicon-containing organic materials was 2.5 μg/m³ when the humidification was not performed.

### NINTH EMBODIMENT

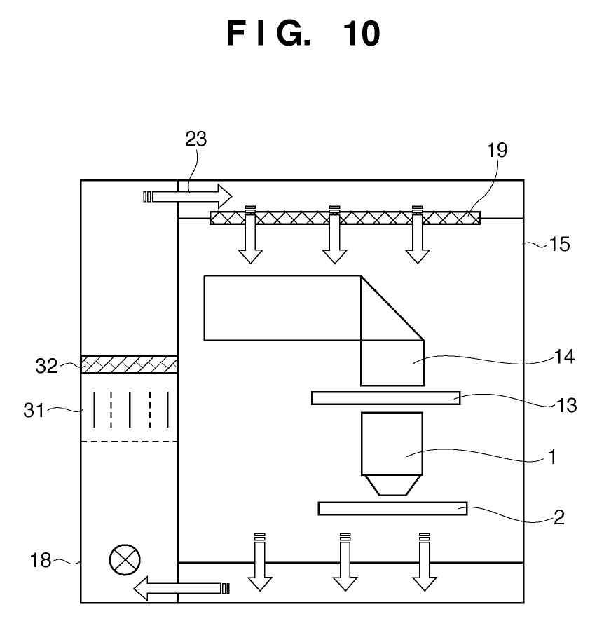

FIG. 10 is a view showing the schematic arrangement of an exposure apparatus according to the ninth embodiment of the present invention. The ninth embodiment is different from the third embodiment in that a low-temperature plasma decomposing device 31 is inserted in a circulation unit. The air recovered into the circulation unit from the floor of an exposure apparatus portion flows through the discharge electrode of the low-temperature plasma decomposing device 31, and is decomposed by radicals and ozone generated in it. The electrodes of the low-temperature plasma decomposing device 31 can be of, for example, the creeping discharge scheme. The ozone is reduced by an ozonolysis catalyst 32 inserted in the subsequent stage of the low-temperature plasma decomposing device 31, and is returned into the exposure apparatus portion through a filter. While the decomposing device was OFF, the density of silicon-containing organic materials near an original stage was 5.4 μg/m³ at a circulation flow rate of 50 l/min. When a voltage of 4 KV is applied across the electrodes, the density of silicon-containing organic materials changed to 1.3 μg/m³ while the decomposing device was in a stable state after it had been in operation for about 6 hours or more. This decreased the rate of adhesion of the silicon-containing organic materials onto the optical element to about ¼.

### 10TH EMBODIMENT

A photocatalytic organic material decomposing device is provided in a circulation system of a humid atmosphere as a silicon-containing organic material decomposing unit in an exposure apparatus similar to that in the seventh embodiment. The purge air which has flown through the vicinity of the optical path flows through the channel, undergoes impurity removal by a chemical filter 55, further flows through the photocatalytic organic material decomposing device, and is returned into the optical path. The photocatalytic organic material decomposing unit is configured such that the atmosphere flows on the surface of a substrate coated with TiO₂. The substrate coated with TiO₂ is illuminated with ultraviolet rays by an ultraviolet lamp.

Upon being irradiated with ultraviolet rays, the TiO₂ is activated, and the density of silicon-containing organic materials decreases gradually. The density of silicon-containing organic materials, which was 3 μg/m³ near an original stage of an exposure apparatus portion while the decomposing device was OFF, decreased to 1.8 μg/m³ while the decomposing device was in a stable state after the ultraviolet lamp had been ON for 12 hours or more.

### [Application Example]

A device manufacturing method according to a preferred embodiment of the present invention is suitable for manufacturing, for example, a semiconductor device and a liquid crystal device. The method can include the steps of transferring the pattern of an original onto a photosensitive agent applied on a substrate using the above-described exposure apparatus, and developing the photosensitive agent.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2008-054066, filed Mar. 4, 2008, which is hereby incorporated by reference herein in its entirety.

What is claimed is:

1. An exposure apparatus which projects a pattern of an original onto a substrate using exposure light provided by a light source, thereby exposing the substrate to light, the apparatus comprising:
an optical element located in an optical path of the exposure light;
a gas supply configured to supply a gas into a space including the optical path;
a decomposing unit configured to process the gas supplied into the space by said gas supply, thereby decomposing a silicon-containing organic material in the gas; and
a controller configured to control said decomposing unit,
wherein said controller is configured to control said decomposing unit to supply the gas processed by said decomposing unit to said optical element located in the space in at least an adhesion suppressed period for which adhesion of a silicon-containing organic material onto the optical element is to be suppressed, and
the adhesion suppressed period starts when application of the exposure light onto said optical element is stopped, and ends when a predetermined time has elapsed from the start time.

2. The apparatus according to claim 1, wherein an operation of said controller to control said gas supply interlocked with control of a substrate exposure operation which accompanies application of the exposure light to said optical element.

3. The apparatus according to claim 2, wherein said controller is configured to operate said decomposing unit prior to the exposure operation to supply the gas processed by said decomposing unit to said optical element, which is located in the space, before the exposure operation is started.

4. The apparatus according to claim 1, wherein said decomposing unit includes an ozone generator configured to add ozone to the gas supplied into the space by said gas supply.

5. The apparatus according to claim 1, wherein said decomposing unit includes a plasma generator.

6. The apparatus according to claim 1, wherein said decomposing unit includes a photocatalyst.

7. The apparatus according to claim 1, wherein a humidity of the gas processed by said decomposing unit is not less than 5%.

8. The apparatus according to claim 7, further comprising at least one of
a humidifier configured to humidify the gas processed by said decomposing unit, and
a dehumidifier configured to dehumidify the gas processed by said decomposing unit.

9. The apparatus according to claim 1, wherein the predetermined time is at least 0.1 seconds.

10. A device manufacturing method comprising the steps of:
exposing a substrate coated with a photosensitive agent to light using an exposure apparatus; and
developing the photosensitive agent,
wherein the exposure apparatus is configured to project a pattern of an original onto the substrate using exposure light provided by a light source, thereby exposing the substrate to light, and comprises:
an optical element located in an optical path of the exposure light;
a gas supply configured to supply a gas into a space including the optical path;
a decomposing unit configured to process the gas supplied into the space by the gas supply, thereby decomposing a silicon-containing organic material in the gas; and
a controller configured to control the decomposing unit,
wherein the controller is configured to control the decomposing unit to supply the gas processed by the decomposing unit to the optical element located in the space in at least an adhesion suppressed period for which adhesion of a silicon-containing organic material onto the optical element is to be suppressed, and
the adhesion suppressed period starts when application of the exposure light onto the optical element is stopped, and ends when a predetermined time has elapsed from the start time.
